(19) United States
(12) Patent Application Publication
(10) Pub. No.: US 2025/0225295 A1
(43) Pub. Date: Jul. 10, 2025

(54) METHOD FOR OPTIMAL RESERVOIR MODEL ADAPTATION BASED ON SPATIOTEMPORAL WELL CONNECTIVITY ANALYSIS UTILIZING TIME DEPENDENT PRODUCTION DATA

(71) Applicant: SAUDI ARABIAN OIL COMPANY, Dhahran (SA)

(72) Inventors: Anton Voskresenskii, Moscow (RU); Nikita Bukhanov, Moscow (RU); Sergey Safonov, Moscow (RU); Klemens Katterbauer, Dhahran (SA); Ali Abdallah Alyousef, Dhahran (SA)

(73) Assignees: Aramco Innovations LLC, Moscow (RU); SAUDI ARABIAN OIL COMPANY, Dhahran (SA)

(21) Appl. No.: 18/700,222

(22) PCT Filed: Jul. 7, 2023
(86) PCT No.: PCT/RU2023/000204

§ 371 Date: Apr. 10, 2024

(51) Int. Cl. G06F 30/27; G06F 30/28; G06N 20/00

(52) U.S. Cl. CPC G06F 30/27; G06F 30/28; G06N 20/00

(57) ABSTRACT

Systems and methods for optimal reservoir model adaptation based on spatiotemporal well connectivity analysis are disclosed. The methods include obtaining production time-series data and metadata from a plurality of wells in a subsurface; preprocessing the production time-series data and the metadata; training a ML model with the preprocessed production time-series data and metadata; predicting a future production times series data with the ML model; determining well connectivity scores of a subsurface with the ML model; detecting a change in reservoir dynamics with a change point method; and modifying a well development plan based on the change in reservoir dynamics.

### BACKGROUND

In the oil and gas industry, forecasting and optimizing production, designing and improving water flooding efficiency, identifying seals, and planning drilling operations are essential for field development. To accomplish these goals, a reservoir model must be created by incorporating multiple data sources that integrate geological and geophysical knowledge. Existing procedures to accomplish these goals include well log data processing, sedimentological analysis, and seismic interpretation. The integration of these data may be carried out on a variety of software platforms by domain experts.

Understanding a reservoir's well connectivity is essential, especially during the early stages of field development when the amount of data relating to the reservoir may be limited. An analysis of reservoir well connectivity may reveal which injectors have an impact on production wells along with the magnitude of their influence. The analysis may also be utilized to adjust existing well-production strategies and increase the effectiveness of water flooding. As field development progresses and the reservoir's response to fluid production is determined, some initial assumptions of reservoir structure may need to be modified to be in agreement with the new data. Consequently, it is important to quantify and understand the characteristics of subsurface connectivity in order to interpret and forecast reservoir response to production.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments are disclosed related to methods for optimal reservoir model adaptation based on spatiotemporal well connectivity analysis. The methods include obtaining production time-series data and metadata from a plurality of wells in a subsurface; preprocessing the production time-series data and the metadata; training a ML model with the preprocessed production time-series data and metadata; predicting a future production times series data with the ML model; determining well connectivity scores of a subsurface with the ML model; detecting a change in reservoir dynamics with a change point method; and modifying a well development plan based on the change in reservoir dynamics.

In general, in one aspect, embodiments are disclosed related to a non-transitory computer-readable memory comprising computer-executable instructions stored thereon that, when executed on a processor, cause the processor to perform the steps of obtaining production time-series data and metadata from a plurality of wells in a subsurface; preprocessing the production time-series data and the metadata; training a ML model with the preprocessed production time-series data and metadata; predicting a future production times series data with the ML model; determining well connectivity scores of a subsurface with the ML model; detecting a change in reservoir dynamics with a change point method; and modifying a well development plan based on the change in reservoir dynamics.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 shows a hydrocarbon producing field with injection and production wells in accordance with one or more embodiments.

FIG. 2 shows a neural network in accordance with one or more embodiments.

FIG. 3 shows Shapley values for well-related features ranked according to largest absolute value in accordance with one or more embodiments.

FIG. 4A shows connectivity scores between three wells over four time intervals in accordance with one or more embodiments.

FIG. 4B shows graphs of well connectivity between three wells over four time intervals in accordance with one or more embodiments.

FIG. 5 shows a workflow of the method in accordance with one or more embodiments.

FIG. 6 shows a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before,” “after,” “single,” and other such terminology. Rather, the use of ordinal numbers is to distinguish between the elements. By way of an example, a first element is distinct from a second element, and the first element may encompass more than one element and succeed (or precede) the second element in an ordering of elements.

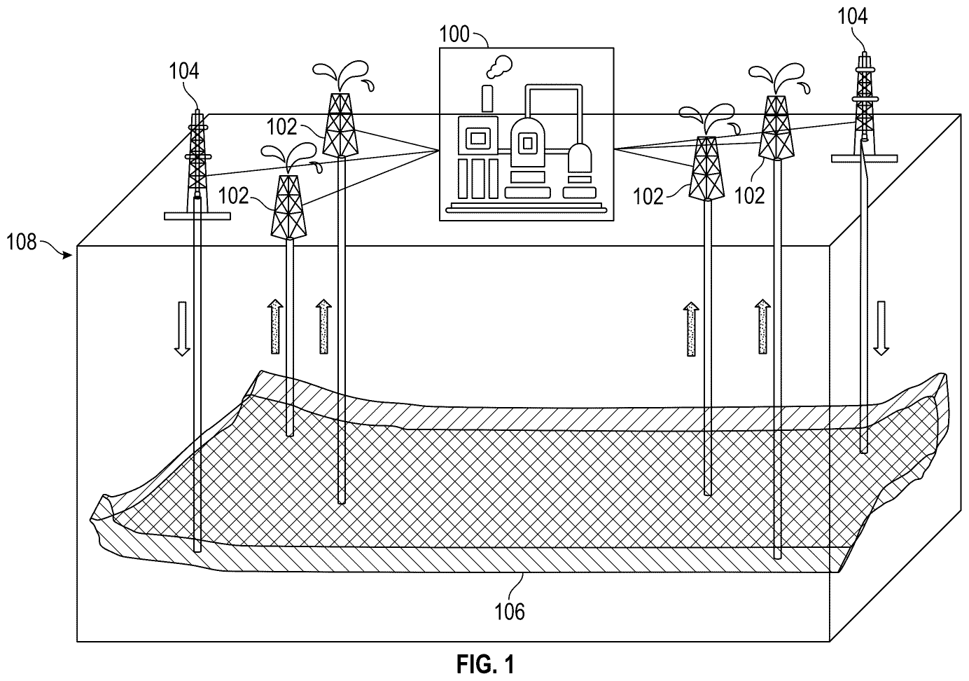

In the following description of FIGS. 1-6, any component described with regard to a figure, in various embodiments disclosed herein, may be equivalent to one or more like-named components described with regard to any other figure. For brevity, descriptions of these components will not be repeated with regard to each figure. Thus, each and every embodiment of the components of each figure is incorporated by reference and assumed to be optionally present within every other figure having one or more like-named components. Additionally, in accordance with various embodiments disclosed herein, any description of the components of a figure is to be interpreted as an optional embodiment which may be implemented in addition to, in conjunction with, or in place of the embodiments described with regard to a corresponding like-named component in any other figure.

It is to be understood that the singular forms “a,” “an,” and “the” include plural referents unless the context clearly dictates otherwise. Thus, for example, reference to “a connectivity score” includes reference to one or more of connectivity scores.

Terms such as “approximately,” “substantially,” etc., mean that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide

It is to be understood that one or more of the steps shown in the flowcharts may be omitted, repeated, and/or performed in a different order than the order shown. Accordingly, the scope disclosed herein should not be considered limited to the specific arrangement of steps shown in the flowcharts.

Although multiple dependent claims are not introduced, it would be apparent to one of ordinary skill that the subject matter of the dependent claims of one or more embodiments may be combined with other dependent claims.

Embodiments disclosed herein describe a system and methods for determining the connectivity between wells. The method first preprocesses all data, removing outliers, and then integrates time-series data and spatial locations of the wells along with production data into a machine learning model. The machine teaming model is used to compute connectivity scores between wells and determine how the wells are affecting each other. Connectivity scores between the wells may be presented as overlapping time series or as a sequence of static graphs. Modeling the graphs over multiple time windows allows for the creation of a time-dependent dynamic graph. A change point detection method may be applied to the dynamic graph across time increments to determine when sharp changes to well connectivity occur. The evolution of the graphs through time provide an understanding of the dynamic structure of a reservoir and can predict the future state of connectivity and the future influence of wells upon each other.

The method may be used as a tool for evaluating points in time when geological or production models should be updated. This method can also be useful in determining optimal locations to place a new well. The method further allows evaluation of injector-producer interactions in order to improve water flooding efficiency, and may be used as a decision-making tool for an infill drilling program.

FIG. 1 depicts a oil field (108) with a plurality of production wells (102), and a plurality of injection wells (104) according to one or more embodiments. Although, for clarity, only a small number of production and injection wells (104) are displayed, typically many production and injection wells (104) may penetrate a hydrocarbon reservoir (106) in an oil field (108). Production wells (102) draw raw crude components (crude, salt water, and gas), from the hydrocarbon reservoir (106) in the oil field (108). Each production well (102) is connected, usually by a pipeline, to a central processing facility (100), where the crude is separated from water and gas. The injection wells (104) re-inject water and gas into the subsurface reservoir (106). Re-injection may serve two purposes: first, disposal of the waste water and gas; and second, to provide pressure support within the hydrocarbon reservoir (106) through, e.g., waterflooding or gas lift. Waterflooding is a process used to inject water into a hydrocarbon reservoir (106) to maintain pressure and/or displace oil so that it is easier to produce. Gas lift refers a method whereby gas is injected into the tubing to reduce the density of the fluids and thereby increase their flow to the surface.

Improving the efficiency of production and injection operations requires an accurate model of the hydrocarbon reservoir (106) being produced. In particular, the connectivity between wells must be known in order to understand how and which injection wells (104) have an impact on which production wells (102). This understanding, in turn, increases the effectiveness of water flooding and gas lift.

Physical methods and numerical simulations may be used to evaluate the connectivity of production wells (102) and injection wells (104) in a hydrocarbon reservoir (106). Physical methods include geochemical analysis, interference well test analysis, and tracer tests. Despite the fact that physical methods can reliably determine interwell connectivity, they may involve long-term shut ins and interrupt well production. Depending on the distance between wells and the hydrocarbon reservoir's (106) hydraulic diffusivity, typical interference testing can frequently take several weeks or even longer.

The numeric simulation approach can quantitatively assess connectivity and its dynamic changes, and requires significant programming effort and computational resources to construct and run a simulation. The results of the simulation also depend on an expert's understanding of physical properties, boundary conditions, and initial conditions which, in turn, can distort the results—especially in the early stages of field development.

As an alternative approach, machine learning (ML) methods can build a reservoir forecasting model based on historical production time-series data. The ML model may then analyze connectivity, and quickly conduct a virtual interference test without the need to physically shut in production wells (102) or program a reservoir simulation model.

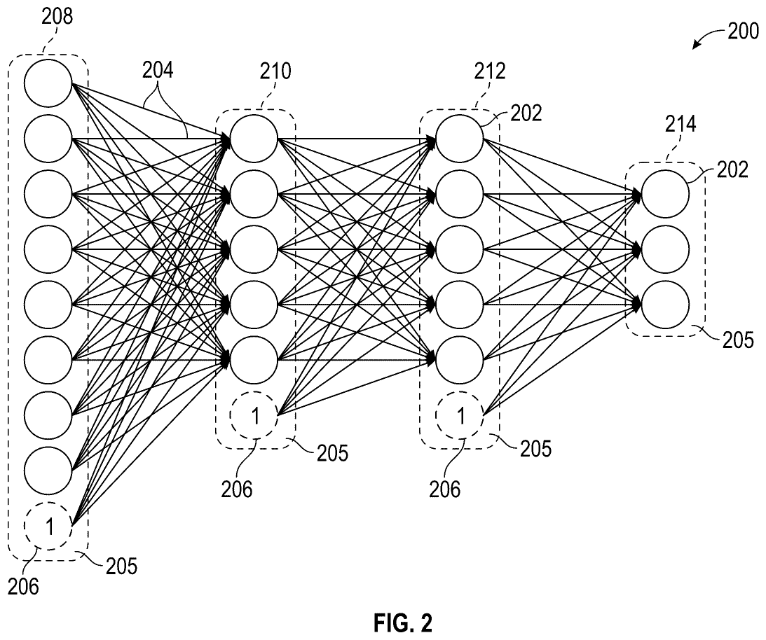

FIG. 2 shows a neural network 1200), a common ML architecture for prediction/inference. Although not all ML models are neural networks (200), and other ML models are used for prediction in embodiments disclosed herein, the neural network (200) is presented here as an archetypal ML model. At a high level, a neural network (200) may be graphically depicted as comprising nodes (202), shown here as circles, and edges (204), shown here as directed lines connecting the circles. The nodes (202) may be grouped to form layers, such as the four layers (208, 210, 212, 214) of nodes (202) shown in FIG. 2. The nodes (202) are grouped into columns for visualization of their organization. However, the grouping need not be as shown in FIG. 2. The edges (204) connect the nodes (202). Edges (204) may connect, or not connect, to any node(s) (202) regardless of which layer (205) the node(s) (202) is in. That is, the nodes (202) may be fully or sparsely connected. A neural network (200) will have at least two layers, with the first layer (208) considered as the “input layer” and the last layer (214) as the “output layer.” Any intermediate layer, such as layers (210) and (212) is usually described as a “hidden layer.” A neural network (200) may have zero or more hidden layers, e.g., hidden layers (210) and (212). However, a neural network (200) with at least one hidden layer (210, 212) may be described as a “deep” neural network forming the basis of a “deep learning method.” In general, a neural network (200) may have more than one node (202) in the output layer (214). In this case the neural network (200) may be referred to as a “multi-target” or “multi-output” network.

Nodes (202) and edges (204) carry additional associations. Namely, every edge is associated with a numerical value. The numerical value of an edge, or even the edge (204) itself, is often referred to as a “weight” or a “parameter.” While training a neural network (200), numerical values are assigned to each edge (204). Additionally, every node (202) is associated with a numerical variable and an activation function. Activation functions are not limited to any functional class, but traditionally follow the form:

$$A = f ( {\sum }_{i ∈ ( Iincoming )} [ {( node value )}_{i} {( edge value )}_{i} ] ) , \qquad ( 1 )$$

where i is an index that spans the set of “incoming” nodes (202) and edges (204) and f is a user-defined function. Incoming nodes (202) are those that, when viewed as a graph (as in FIG. 2), have directed arrows that point to the node (2021 where the numerical value is computed. Functional forms of ƒ may include the linear function ƒ(x)=x, sigmoid function

$$f ( x ) = \frac{1}{1 + {e}^{- x}} ,$$

and rectified linear unit function ƒ(x)=max (0,x), however, many additional functions are commonly employed in the art. Each node (202) in a neural network (200) may have a different associated activation function. Often, as a shorthand, activation functions are described by the function ƒ by which it is composed. That is, an activation function composed of a linear function ƒ may simply be referred to as a linear activation function without undue ambiguity.

When the neural network (200) receives an input, the input is propagated through the network according to the activation functions and incoming node (202) values and edge (204) values to compute a value for each node (202). That is, the numerical value for each node (202) may change for each received input. Occasionally, nodes (202) are assigned fixed numerical values, such as the value of 1, that are not affected by the input or altered according to edge (204) values and activation functions. Fixed nodes (202) are often referred to as “biases” or “bias nodes” (206), and are depicted in FIG. 2 with a dashed circle.

In some implementations, the neural network (200) may contain specialized layers (205), such as a normalization layer, or additional connection procedures, like concatenation. One skilled in the art will appreciate that these alterations do not exceed the scope of this disclosure.

As noted, the training procedure for the neural network (200) comprises assigning values to the edges (204). To begin training, the edges (204) are assigned initial values. These values may be assigned randomly, assigned according to a prescribed distribution, assigned manually, or by some other assignment mechanism. Once edge (204) values have been initialized, the neural network (200) may act as a function, such that it may receive inputs and produce an output. As such, at least one input is propagated through the neural network (200) to produce an output. Recall that a given data set will be composed of inputs and associated target(s), where the target(s) represent the “ground truth”, or the otherwise desired output. The neural network (200) output is compared to the associated input data target(s). The comparison of the neural network (200) output to the target(s) is typically performed by a so-called “loss function”; although other names for this comparison function such as “error function” and “cost function” are commonly employed. Many types of loss functions are available, such as the mean-squared-error function. However, the general characteristic of a loss function is that it provides a numerical evaluation of the similarity between the neural network (200) output and the associated target(s). The loss function may also be constructed to impose additional constraints on the values assumed by the edges (204), for example, by adding a penalty term, which may be physics-based, or a regularization term. Generally, the goal of a training procedure is to alter the edge (204) values to promote similarity between the neural network (200) output and associated target(s) over the data set. Thus, the loss function is used to guide changes made to the edge (204) values, typically through a process called “backpropagation.”

The loss function will usually not be reduced to zero during training. And, once trained, it is not necessary or required that the neural network (200) exactly reproduce the output elements in the training data set when operating upon the corresponding input elements. Indeed, a neural network (200) that exactly reproduces the output for its corresponding input may be perceived to be “fitting the noise.” In other words, it is often the case that there is noise in the training data (i.e., the inputs sometimes do not correspond exactly with their paired outputs), and it would be preferable if the neural network (200) erred on the side of caution and produced a simpler output than the one implied by the training data. The price to pay for using a “perfect” neural network (200) that fits the noise is that it will be limited to fitting only the training data and not able to generalize to produce a realistic output for a new and different input that has never been seen by it before. An analog of this problem occurs when fitting a polynomial to data points. The higher the degree of the polynomial, the closer the resulting curve will be to fitting all the points (a high enough polynomial is guaranteed to fit all the points). However, higher degree polynomials will tend to diverge quickly away from the fit data point values—hence, a high degree polynomial will not exhibit generalizability.

The nodes (202) in a neural network (200) may represent raw input and output data, but they may also represent features—i.e., numerical transformations that capture the data's most salient aspects. How to determine features is application specific and often requires trial and error.

Autoregressive models are a type of statistical model commonly used in time series analysis, and may be used to model the production time-series data being analyzed here and to predict future values. For classical autoregressive models of time series, a collection of past values can predict future values. While classical autoregressive models typically have only two layers and use linear activation functions, this is not a requirement for autoregressive models in general, and more complex models can be used to capture more complex dependencies in the data. A drawback with traditional autoregressive time-series methods is that they do not take into account the spatial nature of the well connectivity problem (e.g., wells further from a target well should, on average, have a lower connectivity with it, and be less useful for prediction). However, it is possible to extend autoregressive models to incorporate spatial dependence using techniques such as spatial autoregression or Gaussian processes.

Other ML models may be used to predict production time-series data at a target well by using input from other wells. The particular ML model used in this invention is known as the ExtraTrees method. However, embodiments disclosed herein are not limited to the ExtraTrees network and other ML models may be used for the same purpose. Neural networks (200), for example, may also be used for prediction, as well as linear models with regularization, gradient boosting on decision trees, random forest, convolutional neural networks (CNNs), and long short-term memory (LSTM) networks.

The production time-series data being predicted by the ML model may be any dynamic well data including bottom hole pressure (BHP), liquid rate, water cut, and gas oil ratio (GOR), or features of these data. Prediction of the production time-series data in the future at the target well depends on its own current and past values, as well as those of the nearby wells. The input to the ML model in this case would be the collection of data (or features of the data) at the target well and at the nearby wells that are used to predict future data (or future features of the data). The output values are the predicted future data (or features of the future data) at the target well. The training data for the ML model includes all instances of data (or features) at the target well and the nearby training wells collected during a particular time interval. In what follows, “features” refers to either features of data or the raw data itself. Incorporating diverse features enhances the ML method's ability to capture temporal and spatial dependencies, thus improving its predictive performance. Some examples of features may include moving statistics, time aggregations, spatial aggregations, wavelet transforms, and singular value decompositions of data values. Other features, specific to the applications presented above, may include choke sizes, a time since last shutdown, and a time since last start. An extended list of possible features of the production time-series data include:
Trends: The overall direction or tendency of the data, indicating whether it is increasing, decreasing, or stationary over time.
Lagged Variables: The values of the series at previous time points, used as predictors to capture dependencies between past and future observations.
Rolling Statistics: Calculating statistical measures, such as moving averages or standard deviations, over a sliding window of observations to capture local trends and fluctuations.
Fourier transform: Decomposing the time series into a sum of sinusoidal components with different frequencies, revealing periodic patterns and dominant frequencies.
Entropy: A measure of the unpredictability or information content in the data, indicating the level of disorder or randomness present.
Spectral Analysis: Analyzing the frequency content of the time series using techniques like the power spectral density, periodogram, or spectrogram.

Although predicting the future values of the production time series is useful for forecasting well performance, the primary goal of training the ML model is not to predict the time series, but rather, to determine well connectivity. This is done by calculating a measure of feature importance, referred to here as a ‘weight.’ during training of the ML model. Shapley values are presented here as the weight, but the method is not limited to Shapley values. Other weights, such as, e.g., mean decrease impurity (MDI), or LIME, may also be used. The weights tell which input nodes of the neural network (200) or other ML model have the most effect on output node predictions. Since the nodes (202) correspond to features in the production time series at the target well and at nearby wells, the weights give a measure of how much the features from each well affect the prediction of future values of features in the target well. Put simply, the weights give a sense of which nodes (202) (i.e., which features) in the ML model have the most impact on predicted output.

Again, the Shapley value is a concept used to determine how much each feature contributes to the output of a machine learning model. It assigns a value to each feature based on how much it contributes to the overall prediction. Shapley values of a feature in a ML model give credit to that feature based on how much it contributes to the final prediction. For the purposes presented here, a Shapley value may assign a value to each feature based on how much it affects the predicted, e.g., the BHP or oil flowrate. By understanding the Shapley value of each feature, one may identify which features are the most important in the model and which can be ignored or removed without significantly affecting the prediction.

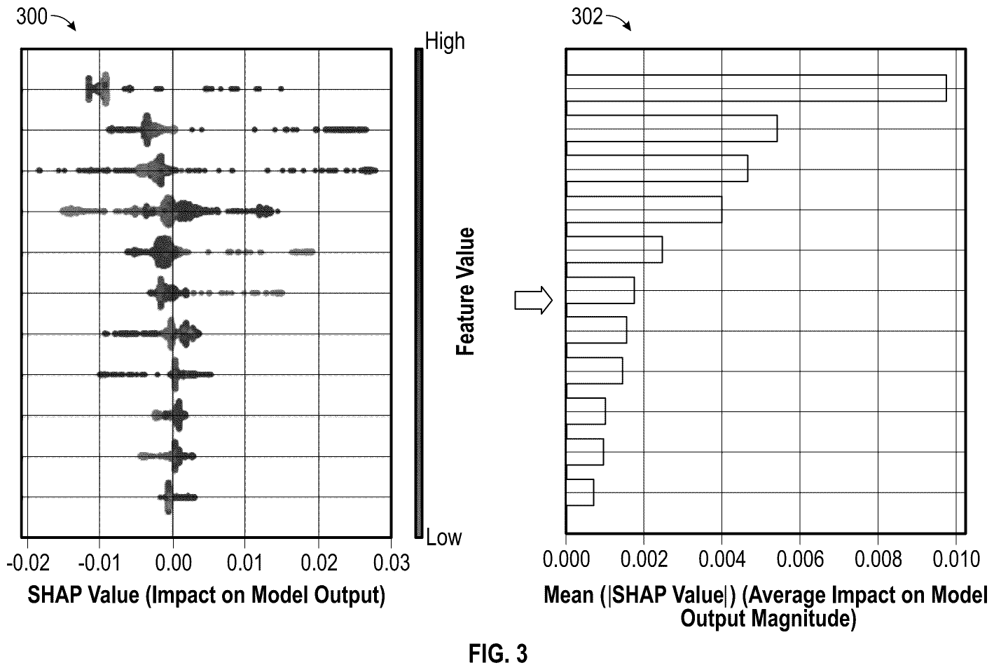

FIG. 3 presents Shapley values on a left graph (300) for features pertaining to well production where each line on the y-axis represents a feature, and the x-axis is the Shapley value, determined when an input is run through the ML model to generate an output. Each sample input to the ML model generates a point on each feature's line in the left graph (300). Clusters show the typical Shapley value resulting from the inputs. If the Shapley value of a feature is large and positive, the ML model tends to predict a larger and more positive output value when the input has a high value. Similarly, if a Shapley value is large and negative, the ML model tends to predict a larger and more negative output value when the input has a high value. In other words, positive Shapley values imply correlated effects of an input on the output, while negative Shapley values imply an anticorrelated effect of an input on the output. Put another way, positive Shapley values indicate that a feature has a positive effect on the predicted output value of a ML model when the input has a high value.

A mean Shapley value can be calculated on each line in the left graph (300). The greater the absolute mean value of a particular feature, the higher that feature is placed on the y-axis of the left graph (300). Dots are shaded according to the feature's value for that sample and pile up vertically to show density. On the right graph (302) of FIG. 3, the absolute values of the mean Shapley value are plotted as a bar for each feature. For each well, the absolute values of all input features are summed to give a connectivity score between that particular well and the target well. A higher connectivity score implies that the corresponding two wells must be more highly connected through fracture networks or geological formations. Thus production or injection at the well has a higher impact on the production of a target well.

By performing the same training of the ML model in different time intervals, changes in the connectivity scores may be observed. Connectivity scores may then be treated as another spatiotemporal time series that tracks well connectivity over time.

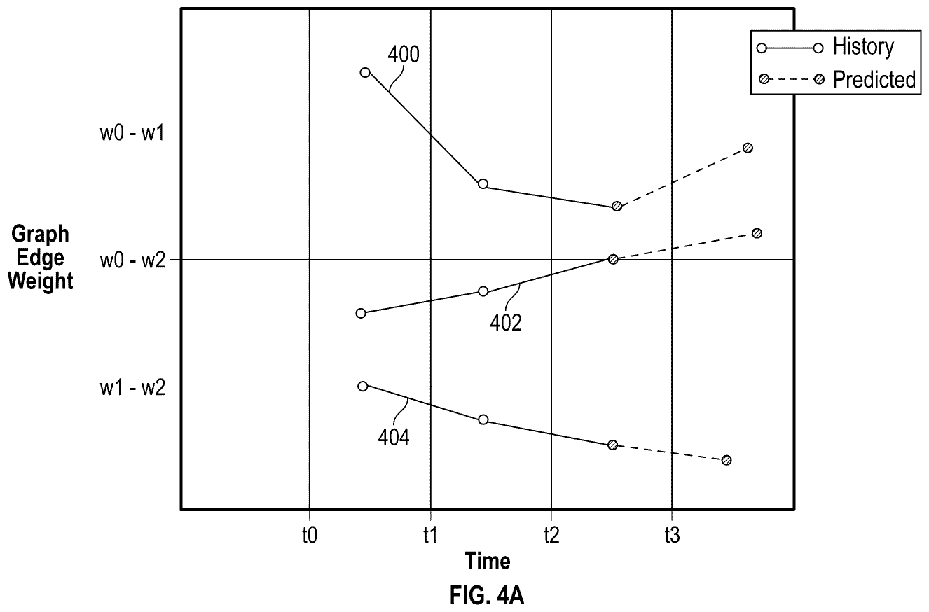

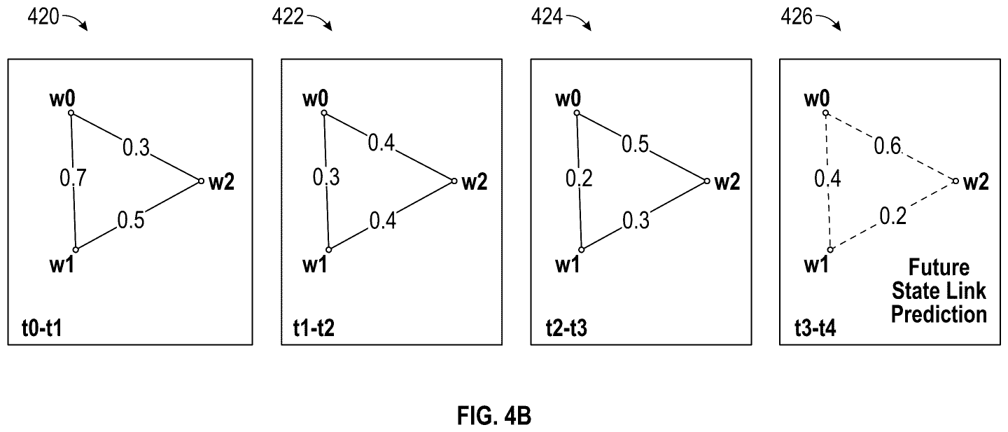

Connectivity scores are plotted in FIGS. 4A and 4B, which present two ways for showing the time evolution of a dynamic graph. In this example, there are three wells, w₀-w₁, and w₂. In FIG. 4A, the time evolution of the connectivity scores of the three wells is shown as three stacked curves. The top curve (400) is the connectivity score over time between w₀ and w₁. The middle curve (402) is the connectivity score over time between w₀ and m₂. The bottom curve (404) is the connectivity score over time between w₁ and w₂. On the horizontal axis are three time intervals, t₀, t₁, and t₂ with observed values of connectivity scores, and a fourth interval, t₃, with a predicted future value of connectivity scores (indicated by the dashed segment of the three curves). Within each time window of FIG. 4A, the connectivity scores may be used to construct a static graph of well connectivity.

These static graphs are shown in FIG. 4B, each from a different time interval. Here the four images represent a spatial graph of the three wells, each in a different time interval. The three time intervals, t₀, t₁, and t₂, show a first graph (420), a second graph (422), and a third graph (424) that represent the observed value of the connectivity scores with that particular time interval. The last graph (426) represents the fourth time interval, t₄, and is a future prediction of the connectivity scores between the three wells. Looking across time windows in FIG. 4B, the connectivity scores define a dynamic graph that shows the evolution of well connectivity over time.

Given the time-evolving spatiotemporal graph, it is useful to have an automatic way to detect significant changes in the connectivity between wells, thereby signaling a significant change in the hydrocarbon reservoir (106). When a significant change in the hydrocarbon reservoir (106) occurs, it may be beneficial to reassess and update all the models of the subsurface (e.g., geological, geophysical, petrophysical, etc.).

Points in time when the well connectivity in the hydrocarbon reservoir (106) changes significantly may be evaluated by two approaches: The first treats the connectivity scores obtained in different timeframes as a multivariate time-series data and applies a change point detection method to determine the optimal time of reservoir model updating. Change point detection methods are designed to find abrupt changes in statistical properties of the time-series data. In the context of embodiments disclosed herein, change point detection methods are used to identify significant changes in well connectivity in the reservoir over time and to determine the optimal time of reservoir model updating. The use of the change point detection methods to identify significant changes in well connectivity overtime as pan of a reservoir modeling approach is a novel aspect of the disclosure herein. Changes in the inter-well connectivity may be used to improve injection operations to produce hydrocarbons, identify what wells to seal, determine where to drill wells for infill drilling, and forecast production.

The second approach for change point detection represents connectivity scores as a graph structure at discrete time intervals, and then calculates a measure of dissimilarity between the graphs. To calculate the dissimilarity measure between the graphs, a generalized distance (e.g., a Levenshtein distance) may be calculated between the graph structure at one time interval and that at the next time interval to identify when changes in the connectivity between the wells have occurred. Analysis of the changes in these statistical measures are informative of changes in connectivity in the reservoir properties.

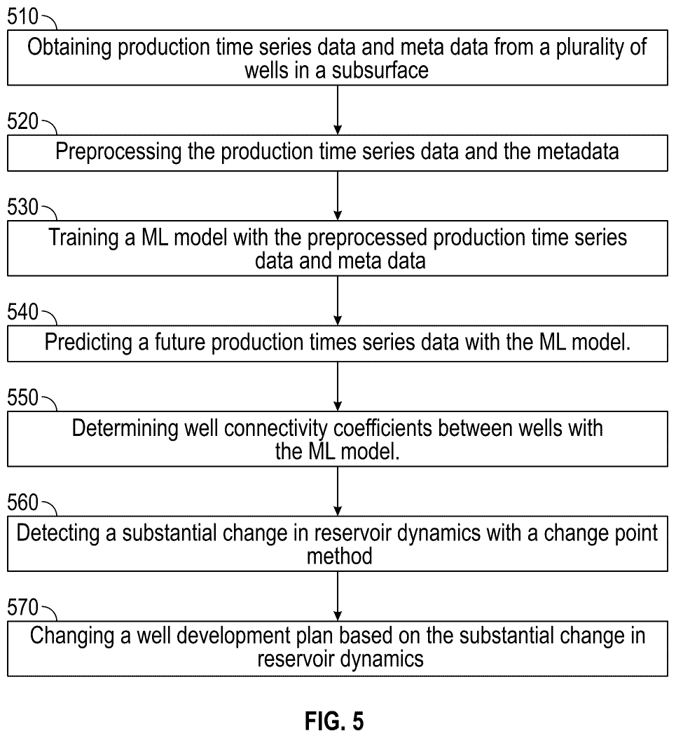

FIG. 5 presents a flowchart of the method for optimal reservoir model adaptation based on spatiotemporal well connectivity analysis utilizing time dependent production data. In Step 510, production time-series data and metadata are obtained from a plurality of wells in a subsurface. The time-series data may include BHP, liquid rate, water cut, and GOR. The metadata may include well coordinates, deviation surveys, a representation of interwell space, development scenarios, a drilling history, and a regional geology. In Step 520, the production time-series data and the metadata are preprocessed to remove outliners and anomalous data points. Features may also be determined from the data at this step and used in lieu of the data. In Step 530, a ML model is trained on the preprocessed production time-series data and metadata. In Step 540, future production time-series data may be predicted with the ML model. In Step 550, well connectivity scores or a subsurface are determined with the ML model. These may come in the form of Shapley values or other weights that measure the influence of the data or feature on the output of the ML model. The connectivity scores may be used to define a graph of connectivity over the wells. The graph, when measured across time intervals (i.e., from t₀ to t₁, t₁, to t₂, etc.), becomes a dynamic graph, with one graph for each time interval. Alternatively, the connectivity scores between a target well and another well may also be represented as a curve, with the x-axis signifying the time interval and the y-axis signifying the connectivity.

In Step 560, a change point method may be used here to detect a change in reservoir dynamics, thus necessitating a revision of reservoir models. In Step 570, a well development plan may be modified based on the detected change in reservoir dynamics and a revised reservoir model.

The advantages of the method of this invention include an ability to quantify the connectivity between wells in a reservoir with a dynamic graph. The method makes novel use of a ML model by analyzing its Shapley values. The Shapley values link which input feature is most associated with an output feature in the ML model. By summing absolute values of Shapley values associated with inputs coming from a particular well, a measure of the total connectivity can be determined between that well and the target well. The method further allows for the Shapley values to be monitored over time, thus detecting when a significant change occurs in reservoir connectivity. The connectivity between wells may be caused my a number of factors, including permeable geologic layers or fractures, as well as movement of fluid through the reservoir. This information about well connectivity may be used to update geological models and thus improve the prediction of hydrocarbon production.

The method is very flexible, allowing the use of a plurality for ML models to predict future time series, a plurality of weights (other than Shapley values), and a plurality of change point methods to determine when a significant change has occurred in the reservoir.

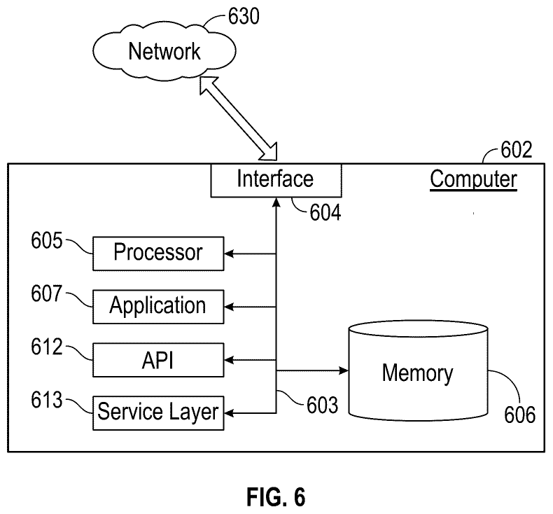

FIG. 6 further depicts a block diagram of a computer system (602) used to provide computational functionalities associated with described algorithms, methods, functions, processes, flows, and procedures as described in this disclosure, according to one or more embodiments. The illustrated computer (602) is intended to encompass any computing device such as a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (602) may include an input device, such as a keypad, keyboard, touch screen, or other device that can accept user information, and an output device that conveys information associated with the operation of the computer (602), including digital data, visual, or audio information (or a combination of information), or a GUI.

The computer (602) can serve in a role as a client, network component, a server, a database or other persistency, or any other component (or a combination of roles) of a computer system for performing the subject matter described in the instant disclosure. The illustrated computer (602) is communicably coupled with a network (630). In some implementations, one or more components of the computer (602) may be configured to operate within environments, including cloud-computing-based, local, global, or other environment (or a combination of environments).

At a high level, the computer (602) is an electronic computing device operable to receive, transmit, process, store, or manage data and information associated with the described subject matter. According to some implementations, the computer (602) may also include or be communicably coupled with an application server, e-mail server, web server, caching server, streaming data server, business intelligence (BI) server, or other server (or a combination of servers).

The computer (602) can receive requests over network (630) from a client application (for example, executing on another computer (602)) and responding to the received requests by processing the said requests in an appropriate software application. In addition, requests may also be sent to the computer (602) from internal users (for example, from a command console or by other appropriate access method), external or third-parties, other automated applications, as well as any other appropriate entities, individuals, systems, or computers.

Each of the components of the computer (602) can communicate using a system bus (603). In some implementations, any or all of the components of the computer (602), both hardware or software (or a combination of hardware and software), may interface with each other or the interface (604)(or a combination of both) over the system bus (603) using an application programming interface (API)(612) or a service layer (613)(or a combination of the API (612) and service layer (613)). The API (612) may include specifications for routines, data structures, and object classes. The API (612) may be either computer-language independent or dependent and refer to a complete interface, a single function, or even a set of APIs. The service layer (613) provides software services to the computer (602) or other components (whether or not illustrated) that are communicably coupled to the computer (602). The functionality of the computer (602) may be accessible for all service consumers using this service layer. Software services, such as those provided by the service layer (613), provide reusable, defined business functionalities through a defined interface. For example, the interface may be software written in JAVA. C⁺⁺, or other suitable language providing data in extensible markup language (XML) format or another suitable format. While illustrated as an integrated component of the computer (602), alternative implementations may illustrate the API (612) or the service layer (613) as stand-alone components in relation to other components of the computer (602) or other components (whether or not illustrated) that are communicably coupled to the computer (602). Moreover, any or all parts of the API (612) or the service layer (613) may be implemented as child or sub-modules of another software module, enterprise application, or hardware module without departing from the scope of this disclosure.

The computer (602) includes an interface (604). Although illustrated as a single interface (604) in FIG. 6, two or more interfaces (604) may be used according to particular needs, desires, or particular implementations of the computer (602). The interface (604) is used by the computer (602) for communicating with other systems in a distributed environment that are connected to the network (630). Generally, the interface (604) includes logic encoded in software or hardware (or a combination of software and hardware) and operable to communicate with the network (630). More specifically, the interface (604) may include software supporting one or more communication protocols associated with communications such that the network (630) or interface's hardware is operable to communicate physical signals within and outside of the illustrated computer (602).

The computer (602) includes at least one computer processor (605). Although illustrated as a single computer processor (605) in FIG. 6, two or more processors may be used according to particular needs, desires, or particular implementations of the computer (602). Generally, the computer processor (605) executes instructions and manipulates data to perform the operations of the computer (602) and any algorithms, methods, functions, processes, flows, and procedures as described in the instant disclosure.

The computer (602) also includes a memory (606) that holds data for the computer (602) or other components (or a combination of both) that can be connected to the network (630). For example, memory (606) can be a database storing data consistent with this disclosure. Although illustrated as a single memory (606) in FIG. 6, two or more memories may be used according to particular needs, desires, or particular implementations of the computer (602) and the described functionality. While memory (606) is illustrated as an integral component of the computer (602), in alternative implementations, memory (606) can be external to the computer (602).

The application (607) is an algorithmic software engine providing functionality according to particular needs, desires, or particular implementations of the computer (602), particularly with respect to functionality described in this disclosure. For example, application (607) can serve as one or more components, modules, applications, etc. Further, although illustrated as a single application (607), the application (607) may be implemented as multiple applications (607) on the computer (602). In addition, although illustrated as integral to the computer (602), in alternative implementations, the application (607) can be external to the computer (602).

There may be any number of computers (602) associated with, or external to, a computer system containing computer (602), wherein each computer (602) communicates over network (630). Further, the term “client,” “user.” and other appropriate terminology may be used interchangeably as appropriate without departing from the scope of this disclosure. Moreover, this disclosure contemplates that many users may use one computer (602), or that one user may use multiple computers (602).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed is:

1. A method, comprising:
obtaining production time-series data and metadata from a plurality of wells in a subsurface;
preprocessing the production time-series data and the metadata;
training a machine learning (ML) model with the preprocessed production time-series data and metadata;
predicting a future production times series data with the ML model;
determining well connectivity scores of a subsurface with the ML model;
detecting a change in reservoir dynamics with a change point method; and
modifying a well development plan based on the change in reservoir dynamics.

2. The method of claim 1, wherein the production time-series data are selected from the following list: a bottom hole pressure, an oil rate, a liquid rate, a water cut, and a gas oil ratio.

3. The method of claim 1, wherein the metadata are selected from the following list: well coordinates, deviation surveys, a representation of interwell space, development scenarios, a drilling history, and a regional geology.

4. The method of claim 1, wherein the ML model is one of the following list: an autoregressive model, an ExtraTrees model, a linear model with regularization, a decision tree with gradient boosting, a random forest, a convolutional neural network, and a long short-term memory model.

5. The method of claim 1, wherein the well connectivity scores are determined from Shapley values.

6. The method of claim 1, further comprising constructing a dynamic graph from the well connectivity scores.

7. The method of claim 6, further comprising determining changes in well connectivity scores with a change point detection method.

8. The method of claim 6, further comprising determining changes in well connectivity scores using a measure of dissimilarity.

9. The method of claim 1, further comprising training the ML model with features of the preprocessed production time-series data.

10. The method of claim 9, wherein the features are selected from the following list: lags, moving statistics, time aggregations, spatial aggregations, trends, rolling statistics, Fourier transforms, an entropy, spectral analysis, choke sizes of injection and production wells, water and gas rates of injection wells, wavelet transforms, singular value decompositions, a time since last shutdown, and a time since last start.

11. A non-transitory computer-readable memory comprising computer-executable instructions stored thereon that, when executed on a processor, cause the processor to perform the steps of:
obtaining production time-series data and metadata from a plurality of wells in a subsurface;
preprocessing the production time-series data and the metadata;
training a machine learning (ML) model with the preprocessed production time-series data and metadata;
predicting a future production times series data with the ML model;
determining well connectivity scores of a subsurface with the ML model;
detecting a change in reservoir dynamics with a change point method; and
modifying a well development plan based on the change in reservoir dynamics.

12. The non-transitory computer-readable memory of claim 11, wherein the production time-series data are selected from the following list: a bottom hole pressure, an oil rate, a liquid rate, a water cut, and a gas oil ratio.

13. The non-transitory computer-readable memory of claim 11, wherein the metadata are selected from the following list: well coordinates, deviation surveys, a representation of interwell space, development scenarios, a drilling history, and a regional geology.

14. The non-transitory computer-readable memory of claim 11, wherein the ML model is one of the following list: an autoregressive model, an ExtraTrees model, a linear model with regularization, a decision tree with gradient boosting, a random forest, a convolutional neural network, and a long short-term memory model.

15. The non-transitory computer-readable memory of claim 11, wherein the well connectivity scores are determined from Shapley values.

16. The non-transitory computer-readable memory of claim 11, further comprising constructing a dynamic graph from the well connectivity scores.

17. The non-transitory computer-readable memory of claim 16, further comprising determining changes in well connectivity scores with a change point detection method.

18. The non-transitory computer-readable memory of claim 16, further comprising determining changes in well connectivity scores using a measure of dissimilarity.

19. The non-transitory computer-readable memory of claim 11, further comprising training the ML model with features of the preprocessed production time-series data.

20. The non-transitory computer-readable memory of claim 19, wherein the features are selected from the following list: lags, moving statistics, time aggregations, spatial aggregations, trends, rolling statistics, Fourier transforms, an entropy, spectral analysis, choke sizes of injection and production wells, water and gas rates of injection wells, wavelet transforms, singular value decompositions, a time since last shutdown and a time since last start.
